(19) United States
(12) Patent Application Publication
(10) Pub. No.: US 2012/0057277 A1
(43) Pub. Date: Mar. 8, 2012

(54) Power Structure of Electronic Products

(76) Inventor: Chu-Ping SHEN, Taipei Hsien (TW)

(21) Appl. No.: 12/875,362

(22) Filed: Sep. 3, 2010

(51) Int. Cl. H05K 5/00

(52) U.S. Cl. 361/679.01

(57) ABSTRACT

The present invention provides an improved power structure of electronic products, which allows to embed at least two thin button cells into the cell holder; multiple grooves are set into the cell holder and attached closely to IC circuit board, such that the anode and cathode of the cell holder are connected electrically with preset contacts on IC circuit board; next, with the circuit design of IC circuit board, the button cells in every groove can provide the electric power continuously in turn, thus extending the service time, saving the storage space of cell holder, and reducing the overall space of the electronic product for stronger competitiveness.

### BACKGROUND OF INVENTION

1. Field of the Invention

The present invention relates generally to a power structure of electronic products, and more particularly to an innovative one which permits multiple thin cells to be embedded into the cell holder and attached to one surface of IC circuit board, thus reducing the overall dimension of the electronic products and extending their service life.

2. Description of Related Art

The commonly used small-sized electronic products are generally fitted with integrated circuit board or IC circuit board, meanwhile a cell holder is also specifically designed to provide the required DC for normal operation.

However, one or more AA or AAA DC cell, or even button cell, is adopted for such electronic products due to the limitation of the dimensional design. If larger power output is required for the cell holder containing multiple cells, these cells are connected in series, otherwise connected in parallel; in both cases, the cell holder occupies a larger space of the electronic products, leading possibly to a projecting shape of the electronic products.

Today, thin-profile, small-sized digital electronic products are developed in response to the prevailing design trend in this field. Yet, the existing cell holder has the shortcomings of complex structure, higher cost and more spare parts with poorer economic benefits; moreover, it is difficult to implement space-saving electronic products given the existing cell holder of larger length and thickness requiring a larger space.

Thus, to overcome the aforementioned problems of the prior art, it would be an advancement if the art to provide an improved structure that can significantly improve the efficacy.

Therefore, the inventor has provided the present invention of practicability after deliberate design and evaluation based on years of experience in the production, development and design of related products.

### CONTENT OF INVENTION

The primary objective of the present invention is to provide an improved power structure of electronic products, which helps to reduce the overall dimension and weight of the electronic products while sharpening their competitive edge in the market.

Another objective of the present invention is to provide an improved power structure of electronic products, which comprises a main supply and a backup supply to extend the service time of the electronic products.

Another objective of the present invention is to provide an improved power structure of electronic products, which introduces a thin-profile cell holder to further simplify the mould design of electronic products for realizing cost-effectiveness and economic benefits.

For above purposes, technical means are adopted to supply power of electronic products with button cells, and design a cell holder incorporated onto the electronic product; at least two grooves are set into the cell holder and attached closely to IC circuit board; the groove is provided with a conducting plate that keeps in contact with the cathode of all button cells to form a common cathode, and at least two conducting strips as an independent anode; the conducting plate and the conducting strips are attached securely to IC circuit board; since button cells can be placed into the groove with a conducting plate and arched conducting strips, in collaboration with the circuit design of IC circuit board, the button cells in every groove can provide the electric power continuously in turn.

In addition, the conducting plate is separated into the same quantity of the conducting strips, and the power line on IC circuit board is planned in such a way that the power supply of the cells is implemented in series, provided that the thin cell holder is not changed.

The present invention is described in detail with reference to the accompanying drawings.

### BRIEF DESCRIPTION OF THE DRAWINGS

FIG. 1: an external view of the preferred embodiment of the present invention that is applied to the electronic product.

FIG. 2: an exploded view of the electronic product in FIG. 1.

FIG. 3: a schematic view of the preferred embodiment of the present invention before it is put into operation.

FIG. 4: a status view of the preferred embodiment of the present invention that is applied to the electronic product.

FIG. 5: a status view of another preferred embodiment of the present invention before it is put into operation.

FIG. 6: a status view of another preferred embodiment of the present invention that is applied to the electronic product.

### SUMMARY OF THE INVENTION

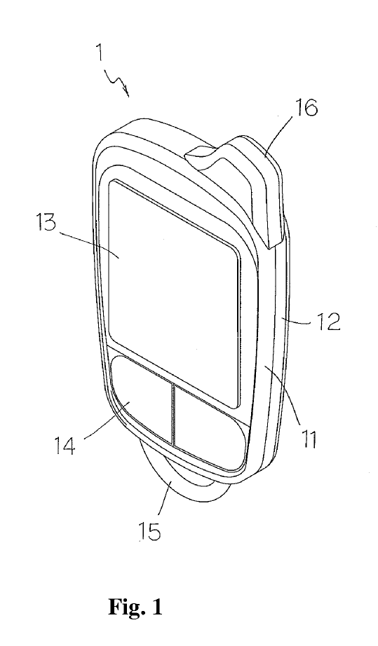

Referring to FIG. 1—an application view of a preferred embodiment of the power structure of the present invention, wherein the electronic product is a common car remote starter 1, which comprising: a face plate 11 and a base 12; the face plate 11 consists of a display screen 13, an operating button 14, a fixing ring 15 and an antenna 16 covered jointly by the face plate 11 and base 12.

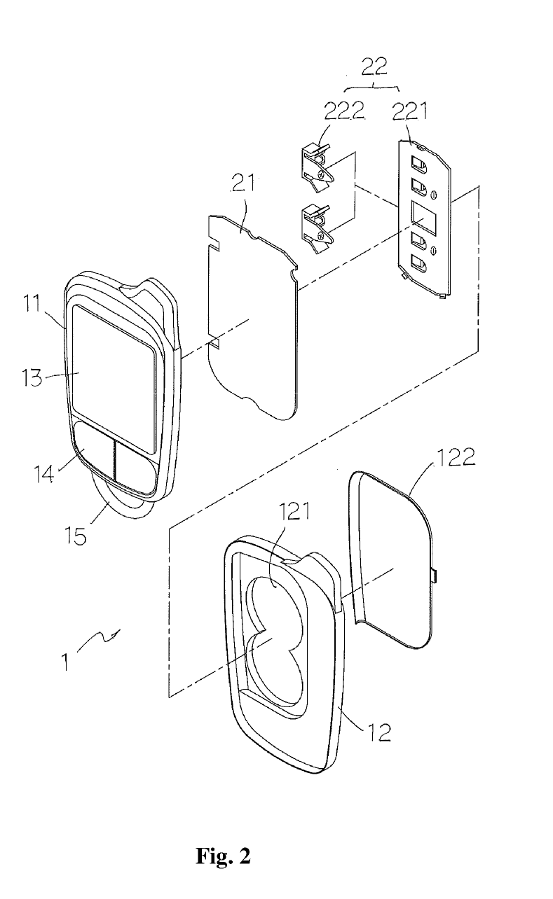

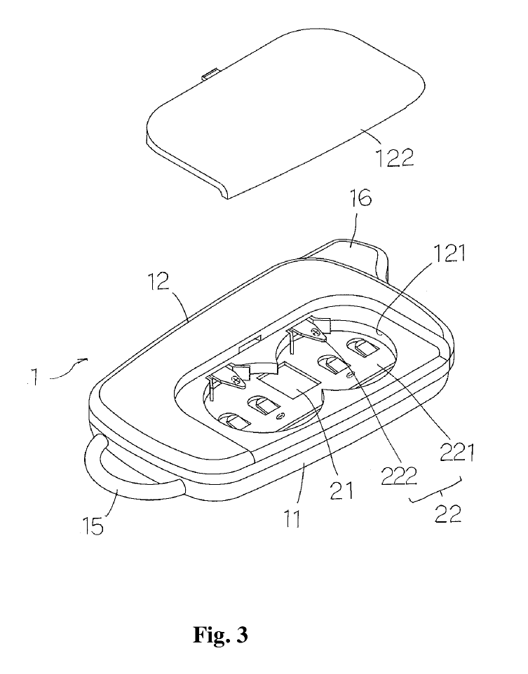

Referring also to FIGS. 2-3, as for said car remote starter 1, an IC circuit board 21 is set into the space between the face plate 11 and the base 12; a cell holder 22 is attached closely to one surface of the IC circuit board 21; the cell holder 22 consists of a conducting plate 221 and two conducting strips 222 as a grip, of which the conducting plate 221 represents cathode, and the conducting strips 222 represent anode; the pins of the conducting plate 221 and conducting strips 222 are connected electrically with preset contacts on the IC circuit board 21, meanwhile an empty slot 121 is set on the base 12 correspondingly to the cell holder 22, so as to form a groove accommodating the button cell 3; the empty slot 121 is fitted with a cover 122 for sealing off.

Said conducting plate 221 as a common cathode is constructed that multiple negative contacts are set, allowing to extend or reduce its length depending on the dimension of the electronic product; the conducting strips 222 as an independent anode are constructed that their quantity can be increased or decreased horizontally by the quantity of negative contacts on the conducting plate 221; moreover, the power line on the IC circuit board 21 is designed for continuous power supply by turns; for the cell holder 22 of a car remote starter 1 shown in FIG. 3, two button cells 3 are embedded and arranged in parallel, thus increasing the efficiency of the car remote starter 1. Similarly, the service time is longer when the quantity of button cells 3 in the cell holder 22 is growing.

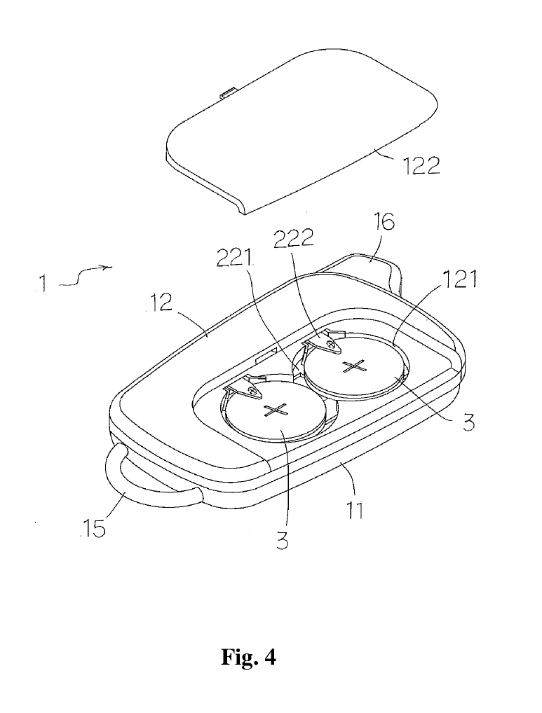

Referring to FIG. 4—a status view of a preferred embodiment of the electronic product of the present invention, wherein the electronic product is a car remote starter 1; two button cells 3 are embedded into the cell holder 22, then the cathode is connected electrically with the conducting plate 221, and the anode connected electrically with the conducting strips 222, next sealed off by a cover 122 to prevent the button cells 3 from loosening or coming-off and ensure normal contact and electrical conductance. With this design, when the car remote starter 1 is used, long-lasting operation is made possible by the power supply from the button cells 3.

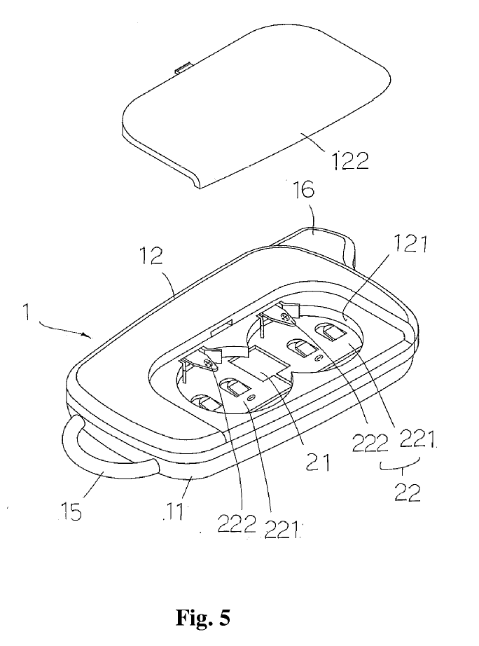

Referring to FIG. 5, the cell holder 22 for the electronic product can be implemented by a parallel supply structure combining the cathode's conducting plate 221 with the anode's conducting strips 222, or by a series power supply mode; in the practice, the conducting plate 221 as cathode in the cell holder 22 is separated into the same quantity of the conducting strips 222 as anode; in such case, multiple button cells can be used for series power supply via the circuit design of the IC circuit board 21.

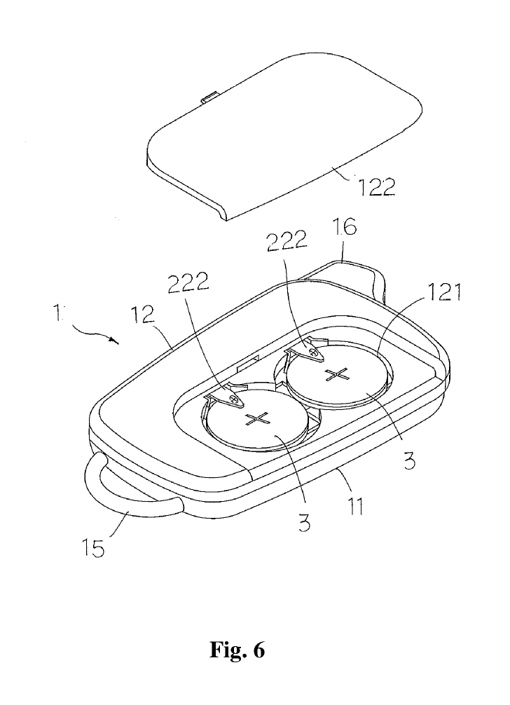

Referring to FIG. 6, when said cell holder 22 for series power supply is applied to the car remote starter 1, two button cells 3 are embedded into the cell holder 22, then the anode and cathode are electrically connected with the conducting plate 221 and conducting strips 222, respectively, and sealed off by the cover 122 to finish the assembly of button cells 3. With this design, efficient operation is made possible by the power supply from these two button cells 3.

The innovative power structure of the present invention, based on the design principle for developing thin-profile and lightweight electronic products, adopts thin button cells as its power supply, arranges horizontally the cell holder and attaches onto IC circuit board to reduce the overall area of the electronic product. In such case, the cell holder and IC circuit board are extended horizontally, without increasing the longitudinal height or obstructing other electronic components to implement the electronic product with smaller area. Moreover, among multiple button cells embedded into the cell holder, one is for operation and the others for backup, thus extending greatly the service time. In addition, the parallel power supply can be easily converted to series power supply provided that the size of cell holder is not changed.

The present invention allows to arrange horizontally the cell holder onto the IC circuit board to accommodate thin button cells, helping to reduce the space without affecting normal power supply functions; as the present invention is an innovative product not yet publicly available complying with the spirit of new patents, the patent claims are made hereto.

1. An improved power structure of the electronic products, which attaches the cell holder closely to the IC circuit board; it is characterized by that:
the cell holder consists of a conducting plate and at least two conducting strips as a grip; of which the conducting plate represents a common cathode, and the conducting strip represents an independent anode; the pins of the conducting plate and conducting strips are connected electrically with preset contacts on the IC circuit board.

2. The improved power structure of the electronic products as claimed in claim 1, wherein said electronic product is a car remote starter.

3. The improved power structure of the electronic products as claimed in claim 1, wherein the conducting plate can be separated into the same quantity of the conducting strips.
